(19) United States
(12) Patent Application Publication
(10) Pub. No.: US 2024/0043719 A1
(43) Pub. Date: Feb. 8, 2024

(54) POLISHING COMPOSITION FOR SEMICONDUCTOR PROCESSING,METHOD FOR PREPARING POLISHING COMPOSITION, AND METHOD FOR MANUFACTURING SEMICONDUCTOR ELEMENT TO WHICH POLISHING COMPOSITION IS APPLIED

(71) Applicant: SKC ENPULSE CO., LTD., Gyeonggi-do (KR)

(72) Inventors: Han Teo PARK, Seoul (KR); Deok Su HAN, Seoul (KR); Jang Kuk KWON, Seoul (US); Seung Chul HONG, Seoul (KR)

(21) Appl. No.: 18/255,958

(22) PCT Filed: Oct. 18, 2021
(86) PCT No.: PCT/KR2021/014487

§ 371 Date: Jun. 5, 2023

(30) Foreign Application Priority Data
Dec. 30, 2020 (KR) 10-2020-0187435
Oct. 18, 2021 (KR) 10-2021-0138183

(51) Int. Cl. C09G 1/02; H01L 21/306

(52) U.S. Cl. CPC C09G 1/02; H01L 21/30625

(57) ABSTRACT

The present invention relates to a polishing composition for a semiconductor process, a method of preparing the polishing composition, and a method of fabricating a semiconductor device using the polishing composition, and specifically, to a polishing composition which is applied to a process of polishing an amorphous carbon layer (ACL). The polishing composition may exhibit a high removal rate of the amorphous carbon layer, does not cause the problem that the removal rate is lowered at 45° C. or higher. In addition, the polishing composition has increased long-term storage stability, may prevent carbon residue generated during the polishing process from being adsorbed onto the semiconductor substrate, and may prevent contamination of the polishing pad. The present invention may also provide a method of fabricating a semiconductor device using the polishing composition for a semiconductor process.

### TECHNICAL FIELD

The present invention relates to a polishing composition for a semiconductor process, a method of preparing the polishing composition, and a method of fabricating a semiconductor device using the polishing composition.

### BACKGROUND ART

As semiconductor devices have become finer and denser, techniques for forming finer patterns have been used, and accordingly, surface structures of semiconductor devices have become more complex and the step difference between interlayer dielectric layers have also increased. In fabrication of a semiconductor device, a chemical mechanical polishing (hereinafter referred to as “CMP”) process is used as a planarization technique for removing a stepped portion from a specific layer formed on a substrate.

In the polishing process, a surface of a substrate is polished while a slurry is provided to a polishing pad and the substrate is pressed and rotated. A target to be planarized varies depending on a step of the process, and there is also a difference in physical properties of the slurry applied at this time.

Specifically, the polishing process has been applied to the planarization of dielectric layers such as silicon oxide (SiO₂) and silicon nitride (SiN), and is also essentially used in planarization processes for metal wiring layers such as tungsten (W) and copper (Cu).

As semiconductor devices have become highly integrated, formation of finer patterns and multi-layered circuits has been required.

To this end, layers of various materials having different etch selectivity characteristics are required. Among these layers of various materials, carbon-based organic layers have good etch selectivity with respect to other silicon-containing layers, and thus may be used as mask layers or sacrificial layers.

In a semiconductor fabrication process, it is required to remove an organic layer by performing a chemical mechanical polishing process on the organic layer. However, a polishing composition capable of efficiently polishing an organic layer, which is applied in a semiconductor fabrication process, by applying the polishing process to the organic layer, has not been developed.

It is necessary to develop a polishing composition for a semiconductor process that is capable of solving the above-described problems.

### DISCLOSURE

### Technical Problem

An object of the present invention is to provide a polishing composition for a semiconductor process, a method of preparing the polishing composition, and a method of fabricating a semiconductor device using the polishing composition.

Another object of the present invention is to provide a method of preparing a polishing composition containing a stabilizer, in which the polishing composition may exhibit a high removal rate and prevent the occurrence of defects in a polishing process, through stabilization of an accelerator in the polishing composition.

Still another object of the present invention is to provide a polishing composition for a semiconductor process, which may be applied to a process of polishing an amorphous carbon layer (ACL), may exhibit a high removal rate of the ACL, may prevent carbon residue generated during the polishing process from being adsorbed onto a semiconductor substrate, and may prevent contamination of a polishing pad.

Yet another object of the present invention is to provide a method of fabricating a semiconductor device using a polishing composition for a semiconductor process.

### Technical Solution

To achieve the above objects, a polishing composition for a semiconductor process according to one embodiment of the present invention may contain abrasive particles, an accelerator, and a stabilizer, wherein the stabilizer may be a compound represented by Formula 1 below:

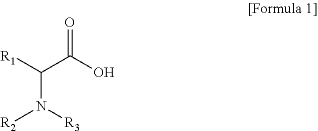

wherein
R₁ to R₃ may be the same as or different from one another and may be each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent substituent to form a ring.

A method of preparing a polishing composition for a semiconductor process according to another embodiment of the present invention may include steps of: a) preparing a polishing solution by mixing a stabilizer and an accelerator in a solvent; b) adjusting the pH of the polishing solution to 2 to 5 by adding a pH adjusting agent to the polishing solution; and c) mixing a surfactant and abrasive particles with the polishing solution having a pH of 2 to 5.

A method of fabricating a semiconductor device according to still another embodiment of the present invention may include steps of: 1) providing a polishing pad including a polishing layer; 2) supplying a polishing composition for a semiconductor process to the polishing pad; and 3) polishing a polishing target while allowing the polishing target and the polishing pad to rotate relative to each other so that the polishing-target surface of the polishing target comes into contact with the polishing surface of the polishing layer, wherein the polishing composition may contain abrasive particles, an accelerator, and a stabilizer.

### Advantageous Effects

The present invention is directed to a polishing composition which may be applied to a process of polishing an amorphous carbon layer (ACL), may exhibit a high removal rate of the amorphous carbon layer, and does not cause the problem that the removal rate is lowered at 45° C. or higher. In addition, the polishing composition has increased long-term storage stability, may prevent carbon residue generated during the polishing process from being adsorbed onto the semiconductor substrate, and may prevent contamination of the polishing pad.

The present invention may also provide a method of fabricating a semiconductor device using the polishing composition for a semiconductor process

### BRIEF DESCRIPTION OF DRAWINGS

FIG. 1 is a schematic view showing a process for fabricating a semiconductor device according to one embodiment of the present invention.

### BEST MODE

The present invention is directed to a polishing composition for a semiconductor process containing abrasive particles, an accelerator, and a stabilizer, wherein the stabilizer is a compound represented by Formula 1 below:

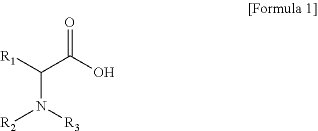

wherein
R₁ to R₃ may be the same as or different from one another and may be each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent group to form a ring.

### Mode For Invention

Hereinafter, embodiments of the present invention will be described in detail so that those skilled in the art can easily carry out the present invention. However, the present invention may be embodied in a variety of different forms and is not limited to the embodiments described herein.

In the present specification, it is to be understood that when any component is referred to as “including” or “containing” another component, it may further include other components, rather than excluding other components, unless otherwise specified.

In the present specification, when any component is referred to as being “connected to” another component, it not only refers to a case where any component is “connected directly to” another component, but also a case where any component is “connected to another component with a third component interposed therebetween”.

In the present specification, the expression “B is located on A” means that B is located directly on A or B is located on A while another layer is located therebetween, and the expression is not construed as being limited to “B is located in contact with the surface of A”.

As used herein, the term “combination thereof” included in any Markush-type expression refers to a mixture or combination of one or more selected from the group consisting of the components described in the Markush-type expression, and is meant to include one or more selected from the group consisting of the above components.

As used herein, the expression “A and/or B” refers to “A”, “B”, or “A and B”.

As used herein, terms such as “first” and “second” or “A” and “B” are used to distinguish the same terms from each other, unless otherwise specified.

In the present specification, singular expressions are intended to include plural expressions as well, unless specified otherwise in the context thereof.

As used herein, the term “hydrogen” refers to hydrogen, protium, deuterium, or tritium.

As used herein, the term “alkyl” refers to a monovalent substituent derived from a linear or branched chain saturated hydrocarbon having 1 to 40 carbon atoms. Examples of the alkyl include, but are not limited to, methyl, ethyl, propyl, isobutyl, sec-butyl, pentyl, iso-amyl, hexyl, and the like.

As used herein, the term “alkenyl” refers to a monovalent substituent derived from a linear or branched chain unsaturated hydrocarbon having 2 to 40 carbon atoms and having at least one carbon-carbon double bond. Examples of the alkenyl include, but are not limited to, vinyl, allyl, isopropenyl, 2-butenyl, and the like.

As used herein, the term “alkynyl” refers to a monovalent substituent derived from a linear or branched chain unsaturated hydrocarbon having 2 to 40 carbon atoms and having at least one carbon-carbon triple bond. Examples of the alkynyl include, but are not limited to, ethynyl, 2-propynyl, and the like.

As used herein, the term “cycloalkyl” refers to a monovalent substituent derived from a monocyclic or polycyclic non-aromatic hydrocarbon having 3 to 40 carbon atoms. Examples of the cycloalkyl include, but are not limited to, cyclopropyl, cyclobutyl, cyclopentyl, cyclohexyl, norbornyl, adamantine, and the like.

As used herein, the term “aryl” refers to a monovalent substituent derived from an aromatic hydrocarbon having 6 to 60 carbon atoms and having a single ring or a combination of two or more rings. In addition, the aryl may also include a form in which two or more rings are simply pendant to each other or fused together. Examples of such aryl include, but are not limited to, phenyl, naphthyl, phenanthryl, anthryl, fluorenyl, dimethylfluorenyl, and the like.

As used herein, the term “heteroaryl” refers to a monovalent substituent derived from a monoheterocyclic or polyheterocyclic aromatic hydrocarbon having 6 to 30 carbon atoms. Here, at least one carbon, preferably 1 to 3 carbons in the ring is substituted with a heteroatom such as N, O, S or Se. In addition, the heteroaryl may also include a form in which two or more rings are simply pendant to each other or fused together, and furthermore, include a form in which two or more rings are fused with an aryl group. Examples of such heteroaryl include, but are not limited to, 6-membered monocyclic rings such as pyridyl, pyrazinyl, pyrimidinyl, pyridazinyl and triazinyl; polycyclic rings such as phenoxathienyl, indolizinyl, indolyl, purinyl, quinolyl, benzothiazole and carbazolyl; 2-furanyl, N-imidazolyl, 2-isoxazolyl, 2-pyridinyl, 2-pyrimidinyl, and the like.

In the present invention, the expression “combined with an adjacent group to form a ring” means being combined with an adjacent group to form a substituted or unsubstituted aliphatic hydrocarbon ring; a substituted or unsubstituted aromatic hydrocarbon ring; a substituted or unsubstituted aliphatic heterocycle; a substituted or unsubstituted aromatic heterocycle; or a fused ring thereof.

Examples of the “aromatic hydrocarbon ring” in the present invention include, but are not limited to, a phenyl group, a naphthyl group, an anthracenyl group, and the like.

As used herein, the term “aliphatic heterocycle” means an aliphatic ring containing one or more heteroatoms.

As used herein, the term “aromatic heterocycle” means an aromatic ring containing at least one heteroatom.

As used herein, the term “substitution” means that a hydrogen atom bonded to a carbon atom of a compound is changed to another substituent, and the position of substitution is not limited as long as it is a position at which the hydrogen atom is substituted, that is, a position at which a substituent can substitute, and when two or more substituents substitute, the two or more substituents may be the same as or different from each other. The substituent may be at least one selected from the group consisting of hydrogen, a cyano group, a nitro group, a halogen group, a hydroxyl group, an alkyl group having 1 to 30 carbon atoms, an alkenyl group having 2 to 30 carbon atoms, an alkynyl group having 2 to 24 carbon atoms, a heteroalkyl group having 2 to 30 carbon atoms, an aralkyl group having 6 to 30 carbon atoms, an aryl group having 5 to 30 carbon atoms, a heteroaryl group having 2 to 30 carbon atoms, a heteroarylalkyl group having 3 to 30 carbon atoms, an alkoxy group having 1 to 30 carbon atoms, an alkylamino group having 1 to 30 carbon atoms, an arylamino group having 6 to 30 carbon atoms, an aralkylamino group having 6 to 30 carbon atoms, and a heteroarylamino group having 2 to 24 carbon atoms, without being limited to the above examples.

Hereinafter, the present invention will be described in more detail.

As semiconductor devices have become finer and denser, surface structures thereof have become more complex. The complexity of the surface structure means that the line width of the semiconductor device is narrowed. The aspect ratio (horizontal-to-vertical ratio) is also gradually increasing, and photoresist is gradually becoming thinner due to the increasing aspect ratio.

However, a phenomenon occurs in which elongate photoresist structures collapse without withstanding the etching process, and a hard mask process has been introduced to prevent this phenomenon.

As the hard mask materials, amorphous carbon and SiON have been used.

The amorphous carbon has excellent etching resistance when used as a hard mask. Nevertheless, when the amorphous carbon is subjected to a chemical mechanical polishing process using a conventional polishing composition, a problem arises in that the removal rate of the amorphous carbon is low and carbon residue is adsorbed onto the surface of the semiconductor substrate due to the generation of carbon residue, causing defects on the semiconductor substrate.

Accordingly, the polishing composition for a semiconductor process according to the present invention may not only exhibit a high removal rate of an amorphous carbon layer, but also prevent re-adsorption of carbon residue, thereby preventing the occurrence of defects on a semiconductor substrate.

Specifically, the polishing composition of the present invention may contain abrasive particles, an accelerator, and a stabilizer, wherein the stabilizer may be a compound represented by Formula 1 below:

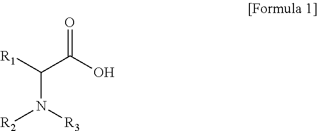

wherein
R₁ to R₃ may be the same as or different from one another and may be each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent substituent to form a ring.

The stabilizer is a component of the polishing composition and may be contained together with the abrasive particles and the accelerator, thereby preventing aggregation of the abrasive particles and increasing the stability of the polishing composition. Thus, the polishing composition may maintain excellent polishing performance even after being used in a polishing process after long-term storage.

The polishing composition of the present invention may be used to polish an amorphous carbon layer (ACL).

A conventional polishing composition used to polish an amorphous carbon layer has a problem in that it exhibits a low removal rate, and thus the polishing efficiency is low. When an amorphous carbon layer is polished using a polishing composition in a semiconductor fabrication process, the polishing rate of the amorphous carbon layer may be 150 Å/min to 250 Å/min, preferably 150 Å/min to 220 Å/min, more preferably 150 Å/min to 210 Å/min. That is, when a polishing composition exhibits a removal rate within the above range in a process of polishing an amorphous carbon layer using the polishing composition, the polishing composition has excellent polishing efficiency, and thus may be applied to the polishing process.

To solve this problem, an accelerator is contained as one component of a polishing composition. When this polishing composition containing the accelerator is used in a polishing process for an amorphous carbon layer, the removal rate may be 150 Å/min to 250 Å/min.

However, when the polishing process was performed at 45° C. or higher, a problem arose in that the removal rate was rapidly lowered, or when the polishing composition was stored for a long period of time, a problem arose in that the removal rate was lowered.

In order to prevent this problem, the polishing composition of the present invention is characterized by containing a stabilizer represented by Formula 1 above. When the polishing composition contains the accelerator and the stabilizer as described above, it may exhibit a high removal rate of the amorphous carbon layer, the problem that the removal rate is lowered does not appear even when the polishing process is performed at 45° C. or higher, and the long-term storage stability of the polishing composition may be maintained.

Specifically, the compound represented by Formula 1 may be a compound represented by Formula 2 or Formula 3 below:

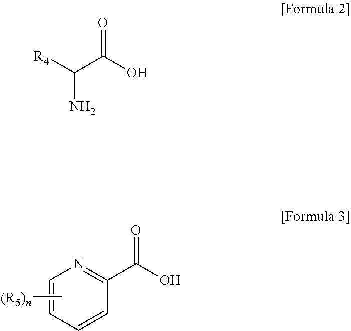

wherein
n is an integer ranging from 0 to 4, and
R₄ and R₅ may be the same as or different from one another and may be each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, and a substituted or unsubstituted alkynyl group having 2 to carbon atoms.

More specifically, R₄ may be a methyl group, and n may be 0, without being limited to the above example, and any stabilizer may be used without limitation as long as it may prevent an aggregation phenomenon by stabilizing the accelerator in the polishing composition, prevent the problem that the removal rate is lowered, even at 45° C. or higher, and improve the long-term storage stability of the polishing composition.

The abrasive particles are abrasive particles applicable to a polishing composition for a semiconductor process, and may be selected from the group consisting of, for example, metal oxide particles, organic particles, organic-inorganic composite particles, and mixtures thereof. The metal oxide particles may be selected from the group consisting of colloidal silica, fumed silica, ceria, alumina, titania, zirconia, zeolite particles, and mixtures thereof, without being limited to the above examples, and any abrasive particles selectable by a person skilled in the art may be used without limitation.

Examples of the organic particles include polystyrene, styrene-based copolymer, poly(meth)acrylate, (meth)acrylate-based copolymer, polyvinyl chloride, polyamide, polycarbonate, or polyimide polymer particles, or core/shell structured particles in which the polymer constitutes a core, a shell, or both, and these particles may be used alone or in combination. The organic particles may be produced by emulsion polymerization, suspension polymerization, or the like.

Specifically, the abrasive particles of the present invention may be selected from the group consisting of colloidal silica, fumed silica, ceria particles, and mixtures thereof.

The abrasive particles may have a diameter (D50) of 10 to 120 nm, preferably a diameter (D50) of 20 to 100 nm, more preferably a diameter (D50) of 40 to 80 nm. When the abrasive particles having a diameter within the above range are contained in the polishing composition and used in a polishing process, it is possible to the occurrence of defects such as scratches on a substrate to be polished, and the abrasive particles have excellent dispersibility.

The accelerator may be selected from the group consisting of anionic small molecules, anionic polymers, hydroxyl acids, amino acids, and cerium salts. Specifically, the cerium salt may be a trivalent cerium salt or a tetravalent cerium salt. More specifically, the tetravalent cerium salt may be selected from the group consisting of cerium (IV) sulfate (Ce(SO₄)₂), ammonium cerium sulfate dihydrate, and cerium ammonium nitrate, without being limited to the above examples.

The accelerator contained in the polishing composition may oxidize the surface layer of the amorphous carbon layer into oxides or ions, thereby facilitating removal of the surface layer of the amorphous carbon layer.

In addition, there is an advantage in that the accelerator allows organic layer material residue present in a polishing stop layer to be easily removed, thereby enabling more uniform polishing.

The cerium ammonium nitrate may be present in the slurry composition in the form of an ionic compound or a chelate compound. When the cerium ammonium nitrite is contained in the form of an ionic compound or a chelate compound as described above, it may exhibit a high removal rate of an amorphous carbon layer.

However, as described above, if only the accelerator is contained to increase the removal rate of the amorphous carbon layer, a problem may arise in that the stability of the polishing composition is low, causing aggregation of the particles, or the removal rate is lowered when the polishing composition is used in a polishing process after long-term storage or the polishing process is performed at 45° C. or higher.

Accordingly, the polishing composition of the present invention is characterized by containing the accelerator and the stabilizer represented by Formula 1. The accelerator may increase the removal rate of the amorphous carbon layer, and the stabilizer may increase the stability of the polishing composition, thereby preventing aggregation of the particles, enabling long-term storage of the polishing composition, and preventing the removal rate from being lowered, even in polishing at 45° C. or higher.

The present invention is directed to a polishing composition having a value of less than 38%, preferably −10% to 15%, more preferably −5% to 5%, as calculated by Equation 1 below:

$$( \frac{{RR}_{0} - {RR}_{f}}{{RR}_{0}} ) \times 100 \qquad [ Equation 1 ]$$

wherein
RR₀ is a removal rate measured after performing polishing using the polishing composition under the following polishing conditions:
a temperature of 15 to 25° C., a polishing head rotation speed of 87 rpm, a platen rotation speed of 93 rpm, an injection rate of the polishing composition of 90 ml/min, a polishing time of 60 second, use of an amorphous carbon wafer having a thickness of 2,000 Å and a size of 4 cm (width)×4 cm (length), and use of a mini-polisher;
RR_{f} is a removal rate measured after performing polishing using the polishing compositions under the above polishing conditions after storing the polishing composition at 45° C. for 10 hours and cooling the polishing composition to 15 to 25° C.; and
RR₀ and RR_{f} are removal rates obtained by measuring the thickness of the amorphous carbon layer before and after performing polishing under the above polishing conditions.

The polishing composition of the present invention has excellent stability, which means that the polishing performance of the polishing composition is not affected by long-term storage. In particular, the storage stability of the polishing composition greatly differs depending on whether or not the stabilizer is contained as one component of the polishing composition.

In order to confirm the difference in the storage stability, the polishing composition may be applied to a polishing process after long-term storage, and a change in the removal rate may be checked. More specifically, the storage stability may be evaluated by storing the polishing composition under stress conditions, applying the polishing composition to a polishing process, and then examining whether a change in the removal rate appears.

This storage stability may be evaluated by Equation 1. RR₀ is a removal rate measured after performing a polishing process using a prepared polishing composition, and RR_{f} is a removal rate measured after performing a polishing process using the polishing composition after keeping the polishing composition in an oven at 45° C. for 10 hours and cooling the polishing composition.

Keeping the polishing composition in the oven at 45° C. as described above corresponds to a stress condition. By checking whether the polishing composition maintains its stability under a temperature condition different from the normal storage temperature, it is possible to indirectly determine whether the polishing composition may be stored for a long time. That is, assuming that storage at 45° C. for 1 hour is equivalent to storage at 15 to 25° C. for one day, storing the polishing composition at 45° C. for 10 hours is considered equivalent to storing the polishing composition at 15 to 25° C. for about 10 days.

The fact that the value calculated by Equation 1 above is included within the scope of the present invention means that the removal rate does not significantly decrease even when the prepared polishing composition is used in the polishing process after stored for a long time. Specifically, the fact means that the removal rate does not change even after storage of the polishing composition for 10 days or more.

In addition, the fact that the value calculated by Equation 1 above is included within the scope of the present invention means that the removal rate is not lowered even when the polishing process is performed at a high temperature of 45° C. That is, RR_{f} is a removal rate measured after using the polishing composition in a polishing process after storing the polishing composition at 45° C. for 10 hours and then cooling the polishing composition to 15 to 25° C. However, considering that the stability of the polishing composition is maintained even after storage at 45° C. for 10 hours, it can be seen that, even when the polishing process is performed at high temperature, the polishing composition does not change and may maintain it stability, thereby exhibiting a high removal rate.

Even after the polishing composition of the present invention is stored for 10 days, a decrease in the removal rate does not appear, indicating that the stabilizer may exhibit an excellent effect on the long-term stability of the polishing composition. On the other hand, it can be seen that a polishing composition that does not contain the stabilizer, unlike the present invention, exhibits no significant difference in the removal rate from the polishing composition containing the stabilizer during the polishing process, at an initial stage after preparation, but the polishing composition that does not contain the stabilizer exhibits a significant reduction in the removal rate after 10 days of storage.

The polishing composition of the present invention contains a surfactant. The surface tension of the polishing composition may be reduced by the surfactant, thereby preventing re-adsorption of carbon residue onto the semiconductor substrate.

If a polishing composition contains an accelerator to increase the removal rate of an amorphous carbon layer, the removal rate increases, but a problem arises in that carbon residue generated during the polishing process is adsorbed onto the semiconductor substrate, thus increasing defects.

In order to solve the above problem, a surfactant is contained in the polishing composition to reduce the surface tension of the polishing composition. As the surface tension is reduced, re-adsorption of carbon residue onto the substrate surface may be prevented.

Specifically, the surfactant may include a nonionic fluorine-based polymer compound. The surfactant includes a fluorine-based polymer compound, and when it is used in a polishing process for an amorphous carbon layer, it may prevent generated carbon residue from being re-adsorbed onto the surface of the semiconductor substrate.

In addition, since the surfactant contains fluorine, it may suppress the multiplication of microorganisms such as bacteria and fungi. If a polishing composition is stored for a long period of time, bacteria and fungi may occur therein, and the polishing composition in which bacteria and fungi have occurred cannot be used in the polishing process and must be discarded.

In the polishing composition of the present invention, the surfactant includes a nonionic fluorine-based polymer compound, and when the polishing composition is stored for a long period of time, the nonionic fluorine-based polymer compound may prevent the occurrence of bacteria and fungi, thereby increasing the long-term storage stability of the polishing composition.

The surfactant of the present invention may be specifically selected from the group consisting of Chemours™ FS-30, FS-31, FS-34, ET-3015, ET-3150, ET-3050, and mixtures thereof, but any surfactant serving to prevent carbon residue from being re-adsorbed onto the surface of a semiconductor substrate in a polishing process may be used without particular limitation.

The surfactant of the present invention may be a nonionic surfactant, and a surfactant including a nonionic fluorine-based polymer compound may be used alone or in combination with other nonionic surfactants.

The nonionic surfactant may be selected from the group consisting of polyethylene glycol, polypropylene glycol, a polyethylene-propylene copolymer, polyalkyl oxide, polyoxyethylene oxide (PEO), polyethylene oxide, and polypropylene oxide, and the fluorine-based surfactant may be selected from the group consisting of a sodium sulfonate fluorosurfactant, a phosphate ester fluorosurfactant, an amine oxide fluorosurfactant, a betaine fluorosurfactant, an ammonium carboxylate fluorosurfactant, a stearate ester fluorosurfactant, a quaternary ammonium fluorosurfactant, an ethylene oxide/propylene oxide fluorosurfactant, and a polyoxyethylene fluorosurfactant.

The polishing composition of the present invention may contain a pH adjusting agent. The pH adjusting agent may be at least one selected from the group consisting of hydrochloric acid, phosphoric acid, sulfuric acid, hydrofluoric acid, nitric acid, hydrobromic acid, iodic acid, formic acid, malonic acid, maleic acid, oxalic acid, acetic acid, adipic acid, citric acid, acetic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, aspartic acid, tartaric acid, and potassium hydroxide.

The pH adjusting agent may adjust the pH of the polishing composition for a semiconductor process to 2 to 5, preferably 2 to 4. When the polishing composition is maintained at an acidic pH within the above range, it is possible to maintain the removal rate and the quality of the polishing composition at certain levels or higher while preventing excessive corrosion of metal components or a polishing device.

The polishing composition for a semiconductor process may include 0.1 wt % to 0.5 wt % of the abrasive particles, 1 wt % to 2 wt % of the accelerator, 1 wt % to 2 wt % of the stabilizer, 0.001 wt % to 0.01 wt % of the surfactant, and the balance of a solvent. When the above components are contained in the polishing composition in amounts within the above ranges, the accelerator may be stabilized by the stabilizer, and thus the removal rate may be increased by the accelerator in the polishing composition, and the occurrence of defects in a polishing process may be prevented by the stabilizer and the surfactant.

The solvent may ultrapure water, but is not limited to the above example, and any solvent may be used without limitation as long as it may be a solvent for the polishing composition.

A method of preparing a polishing composition according to the present invention may include steps of: a) preparing a polishing solution by mixing a stabilizer and an accelerator in a solvent; b) adjusting the pH of the polishing solution to 2 to 5 by adding a pH adjusting agent to the polishing solution; and c) mixing a surfactant and abrasive particles with the polishing solution having a pH of 2 to 5.

In step a), a stabilizer may be mixed with a solvent in order to stabilize an accelerator, thereby preparing a mixed solution, and then the accelerator may be mixed with the mixed solution, thereby preparing a polishing solution.

If a polishing composition is prepared by mixing an accelerator with a stabilizer, a pH adjusting agent, a surfactant and abrasive particles in ultrapure water as a solvent, the accelerator may not be stabilized in the polishing composition, making it difficult to store the prepared polishing composition for a long time, or the effect of increasing the removal rate by the accelerator in the polishing composition may not appear.

To prevent this problem, according to the present invention, a mixed solution is prepared by mixing a stabilizer with a solvent, and a polishing solution is prepared by mixing an accelerator with the mixed solution. Then, the pH of the polishing solution is adjusted within an appropriate range, and a surfactant and abrasive particles are mixed with the polishing solution, thereby preparing a polishing composition. When the polishing composition is prepared according to the above-described method, the stability of the accelerator in the polishing composition may be maintained, making it possible to store the polishing composition for a long time, and it is possible to prevent the problem that the removal rate is lowered when a polishing process is performed at high temperature.

A method of fabricating a semiconductor device according to still another embodiment of the present invention may include steps of: 1) providing a polishing pad including a polishing layer; 2) supplying a polishing composition for a semiconductor process to the polishing pad; and 3) polishing a polishing target while allowing the polishing target and the polishing pad to rotate relative to each other so that the polishing-target surface of the polishing target comes into contact with the polishing surface of the polishing layer, wherein the polishing composition may contain abrasive particles, an accelerator, and a stabilizer, wherein the stabilizer may be may be a compound represented by Formula 1 below:

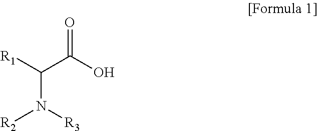

wherein
R₁ to R₃ may be the same as or different from one another and may be each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent substituent to form a ring. Detailed description of the stabilizer will be omitted.

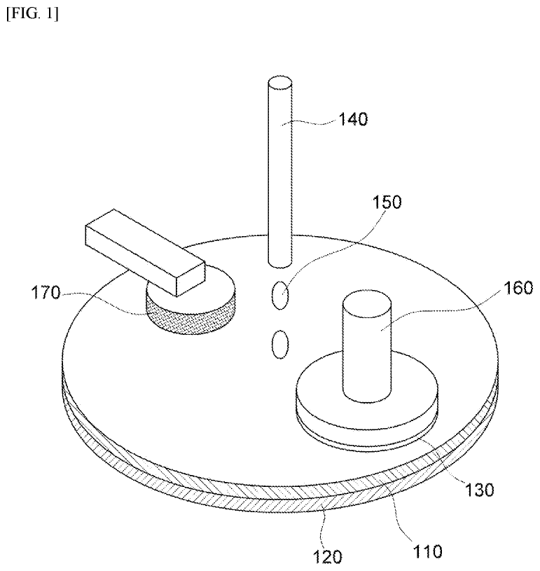

FIG. 1 is a schematic view showing a process for fabricating a semiconductor device according to one embodiment of the present invention. Referring to FIG. 1, according to the embodiment, a polishing pad 110 is mounted on a platen 120, and then a semiconductor substrate 130 as a polishing target is disposed on the polishing pad 110. For polishing, a polishing slurry 150 is sprayed onto the polishing pad 110 through a nozzle 140.

The flow rate of the polishing slurry 150 that is supplied through the nozzle 140 may be selected within the range of about 10 cm³/min to about 1,000 cm³/min depending on the purpose, and may be, for example, about 50 cm³/min to about 500 cm³/min, without being limited thereto.

Here, the polishing-target surface of the semiconductor substrate 130 is in direct contact with the polishing surface of the polishing pad 110.

Next, the semiconductor substrate 130 and the polishing pad 110 may be rotated relative to each other, so that the surface of the semiconductor substrate 130 may be polished. In this case, the rotating direction of the semiconductor substrate 130 and the rotating direction of the polishing pad 110 may be the same direction or may be opposite to each other. The rotating speed of each of the semiconductor substrate 130 and the polishing pad 110 may be selected within the range of about 10 rpm to about 500 rpm depending on the purpose, and may be, for example, about 30 rpm to about 200 rpm, without being limited thereto.

In an example of the substrate polishing process, an organic layer on a substrate may be polished, and the present invention may be applied to a process of polishing a carbon-based organic layer.

Specifically, the carbon-based organic layer may be, for example, a C—SOH (spin-on-hardmask) layer, an amorphous carbon layer, or an NCP layer, and is preferably an amorphous carbon layer on which the polishing composition may have an excellent selective polishing effect and exhibit a high removal rate.

Contents regarding the polishing composition for a semiconductor process overlap with those described above, and thus detailed description thereof will be omitted.

In one embodiment, the method of fabricating a semiconductor device may further include a step of processing the polishing surface of the polishing pad 110 by a conditioner 170 at the same time as polishing of the semiconductor substrate 130 in order to maintain the polishing surface of the polishing pad 110 in a state suitable for polishing.

Preparation of Semiconductor Polishing Compositions

### EXAMPLE 1

Colloidal silica particles were used as abrasive particles. A mixed solution was prepared by mixing ultrapure water with a stabilizer represented by Formula 4 below, and a polishing solution was prepared by mixing cerium ammonium nitrite with the mixed solution.

The pH of the polishing composition was adjusted to 2.1 by adding nitric acid to the polishing solution, and the polishing solution was mixed with Chemours™ FS-30 as a surfactant and colloidal silica having a diameter of 75 nm, thereby preparing a polishing composition.

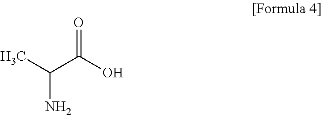

### EXAMPLE 2

A polishing composition was prepared in the same manner as in Example 1, except that a compound represented by Formula 5 below was used as the stabilizer.

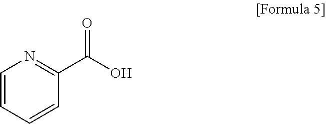

### Comparative Examples 1 to 11

Polishing compositions were prepared in the same manner as in Example 1, except that the kind of stabilizer was changed as shown in Table 1 below.

TABLE 1

| | Kind of stabilizer |
|---|---|
| Comparative Example 1 | Ammonium chloride |
| Comparative Example 2 | Hydrochloric acid |
| Comparative Example 3 | Histidine |
| Comparative Example 4 | Phosphoric acid |
| Comparative Example 5 | Formic acid |
| Comparative Example 6 | Ammonium phosphate |
| Comparative Example 7 | Citric acid |
| Comparative Example 8 | Tartaric acid |
| Comparative Example 9 | Malonic acid |
| Comparative Example 10 | Maleic acid |
| Comparative Example 11 | Oxalic acid |

### Comparative Example 12

A polishing composition was prepared in the same manner as in Example 1, except that it contained no stabilizer.

Specifically, the contents of components in the polishing compositions of Examples 1 and 2 and Comparative Examples 1 to 12 are shown in Table 2 below.

TABLE 2

| | Abrasive | | | | | | |
|---|---|---|---|---|---|---|---|
| | particles | | | Stabilizer | | | |
| | (75 nm) | Accelerator | Surfactant | Kind | Molarity | Content | Solvent |
| Example 1 | 0.25 | 1.3 | 0.005 | Formula 4 | 0.02 | 0.2 | Balance |
| Example 2 | 0.25 | 1.3 | 0.005 | Formula 5 | 0.02 | 0.28 | |
| Comparative | 0.25 | 1.3 | 0.005 | Ammonium | 0.02 | 0.12 | |
| Example 1 | | | | chloride | | | |
| Comparative | 0.25 | 1.3 | 0.005 | Hydrochloric | 0.02 | 0.08 | |
| Example 2 | | | | acid | | | |
| Comparative | 0.25 | 1.3 | 0.005 | Histidine | 0.02 | 0.35 | |
| Example 3 | | | | | | | |
| Comparative | 0.25 | 1.3 | 0.005 | Phosphoric | 0.02 | 0.22 | |
| Example 4 | | | | acid | | | |
| Comparative | 0.25 | 1.3 | 0.005 | Formic acid | 0.02 | 0.1 | |
| Example 5 | | | | | | | |
| Comparative | 0.25 | 1.3 | 0.005 | Ammonium | 0.02 | 0.33 | |
| Example 6 | | | | phosphate | | | |
| Comparative | 0.25 | 1.3 | 0.005 | Citric acid | 0.02 | 0.43 | |
| Example 7 | | | | | | | |
| Comparative | 0.25 | 1.3 | 0.005 | Tartaric acid | 0.02 | 0.34 | |
| Example 8 | | | | | | | |
| Comparative | 0.25 | 1.3 | 0.005 | Malonic acid | 0.02 | 0.23 | |
| Example 9 | | | | | | | |
| Comparative | 0.25 | 1.3 | 0.005 | Maleic acid | 0.02 | 0.26 | |
| Example 10 | | | | | | | |
| Comparative | 0.25 | 1.3 | 0.005 | Oxalic acid | 0.02 | 0.2 | |
| Example 11 | | | | | | | |
| Comparative | 0.25 | 1.3 | 0.005 | — | — | — | |
| Example 12 | | | | | | | |

(Unit: wt %)

### Experimental Example 1

Measurement of Removal Rate

A polishing process was performed using the polishing composition of each of the Examples and the Comparative Examples under the following polishing conditions. For the polishing process, the removal rate was measured, and the result was checked.

Polisher: G&P POLI-400

Polishing pad: SKC PAD HD-319B

Polishing time: 60 seconds

Polishing head rotation speed: 87 rpm

Polishing head pressure: 210 g/cm²

Conditioner force: 16.5 kgf

Conditioner speed: 93 rpm

Platen rotation speed: 93 rpm

Polishing composition injection rate: 90 ml/min

Wafer: ACL wafer (2,000 Å) 4 cm×4 cm

The wafer was polished using a mini-polisher under the above polishing condition, and the wafer thicknesses before and after the polishing were measured using Woollam M-2000 ellipsometer (J.A. Woollam) as a thickness measurement instrument and converted into a removal rate. The measurement results are shown in Table 3 below.

TABLE 3

| | Mini polisher(POLI-400) | | | |
|---|---|---|---|---|
| | Room | High- | | |
| | temperature | temperature | Decrease | |
| | RR* | RR** | rate (%) | Remarks |
| Example 1 | 80 | 81 | −1% | |
| Example 2 | 82 | 79 | 4% | |
| Comparative | 78 | 43 | 45% | |
| Example 1 | | | | |
| Comparative | 82 | 51 | 38% | |
| Example 2 | | | | |
| Comparative | 77 | 29 | 62% | |
| Example 3 | | | | |
| Comparative | 76 | 46 | 39% | |
| Example 4 | | | | |
| Comparative | 85 | 35 | 59% | |
| Example 5 | | | | |
| Comparative | — | — | — | Aggregated |
| Example 6 | | | | |
| Comparative | — | — | — | Aggregated |
| Example 7 | | | | |
| Comparative | — | — | — | Aggregated |
| Example 8 | | | | |
| Comparative | — | — | — | Aggregated |
| Example 9 | | | | |
| Comparative | — | — | — | Aggregated |
| Example 10 | | | | |
| Comparative | — | — | — | Aggregated |
| Example 11 | | | | |

(Removal rate unit: Å/min)
*The polishing process was performed at 15 to 25° C.
**The polishing process was performed after the polishing composition was kept at 45° C. for 10 hours and then cooled at 15 to 25° C.

Referring to Table 3 above, in the case of the polishing compositions of Comparative Examples 6 to 11, it was impossible to measure the removal rate, due to the occurrence of aggregation.

It was confirmed that the polishing compositions of Examples 1 and 2 and Comparative Examples 1 to 5 exhibited a removal rate of 76 Å/min to 85 Å/min when the polishing process was performed at 15 to 25° C. (room temperature RR*), indicating that these polishing compositions exhibited no significant difference in the removal rate.

On the other hand, it was confirmed that, when the polishing process was performed after each of the polishing compositions was kept at 45° C. for 10 hours and then cooled at 15 to 25° C. (high-temperature RR **), the polishing compositions of Examples 1 and 2 exhibited removal rates of 81 Å/min and 79 Å/min, respectively, which were not different from the room-temperature RR*.

On the other hand, in the case of Comparative Examples 1 to 5, the high-temperature removal rate value (high-temperature RR**) decreased by a minimum of 38% and a maximum of 62% compared to room temperature RR*. This suggests that the polishing compositions of Comparative Examples 1 to 5 have poor storage stability.

### Experimental Example 2

Evaluation of Storage Stability

A change in removal rate after long-term storage of each polishing composition was measured. Specifically, after the polishing compositions of Example 1 and Comparative Example 12 were stored for 1 day, 9 days, 15 days, 22 days and 29 days, removal rates were measured under the following conditions.

[Polishing Conditions]

Polisher: AP-300

Polishing pad: HD-319B

Polishing time: 60 seconds

Polishing head rotation speed: 87 rpm

Platen rotation speed: 93 rpm

Polishing composition injection rate: 200 ml/min

Wafer: ACL wafer (2,000 Å) 300 mm

Temperature: 15 to 25° C.

The removal rate was calculated by measuring the thicknesses of the amorphous carbon layer (ACL) wafer before and after the polishing process using J.A. Woollam M-2000 ellipsometer which is a thickness measurement instrument.

TABLE 4

| | 300 mm polishing | | | | |
|---|---|---|---|---|---|
| | Day 1 | Day 9 | Day 15 | Day 22 | Day 29 |
| Example 1 | 189 | 199 | 190 | 181 | 202 |
| Comparative | 139 | 110 | 38 | 34 | 32 |
| Example 12 | | | | | |

(Removal rate unit: Å/min)

Referring to Table 4, it could be confirmed that, in the case of the polishing composition containing no stabilizer, unlike the present invention, the removal rate rapidly decreased after 9 days. Specifically, the removal rate measured after 15 days of storage decreased by about 65% compared to the removal rate measured after 9 days. On the other hand, it was confirmed that, in the case of Example 1 of the present invention, the removal rates measured after 15 days and 22 days of storage slightly decreased compared to the removal rate measured after 9 days, but the removal rate measured after 29 days was the highest, suggesting that the polishing composition of Example 1 exhibited no decrease in the removal rate even after long-term storage.

Although preferred embodiments of the present invention have been described in detail above, the scope of the present invention is not limited thereto, and various modifications and improvements made by those skilled in the art without departing from the basic concept of the present invention as defined by the appended claims also fall within the scope of the present invention.

110: polishing pad

120: platen

130: semiconductor substrate

140: nozzle

150: polishing slurry

160: polishing head

170: conditioner

### INDUSTRIAL APPLICABILITY

The present invention relates to a polishing composition for a semiconductor process, a method of preparing the polishing composition, and a method of fabricating a semiconductor device using the polishing composition.

1. A polishing composition for a semiconductor containing abrasive particles, an accelerator, and a stabilizer,
wherein the stabilizer is a compound represented by Formula 1 below: 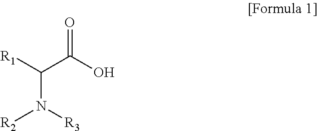
wherein
R₁ to R₃ are same as or different from one another and are each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent group to form a ring.

2. The polishing composition of claim 1, wherein the compound represented by Formula 1 is a compound represented by Formula 2 or 3 below: 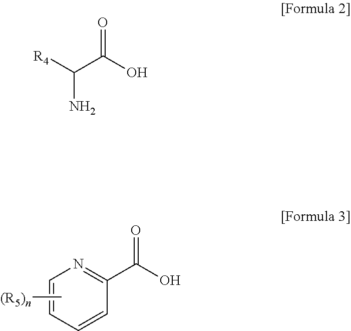
wherein
n is an integer ranging from 0 to 4, and
R₄ and R₅ are the same as or different from each other and are each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, and a substituted or unsubstituted alkynyl group having 2 to 10 carbon atoms.

3. The polishing composition of claim 1, wherein the accelerator is selected from the group consisting of metal oxide particles, organic particles, organic-inorganic composite particles, and mixtures thereof.

4. The polishing composition of claim 1, wherein the accelerator is selected from the group consisting of anionic small molecules, anionic polymers, hydroxyl acids, amino acids, and cerium salts.

5. The polishing composition of claim 1, further containing a surfactant.

6. The polishing composition of claim 1, further containing a pH adjusting agent.

7. The polishing composition of claim 1, having a value of less than 38% as calculated by Equation 1 below:
$$( \frac{{RR}_{0} - {RR}_{f}}{{RR}_{0}} ) \times 100 \qquad [ Equation 1 ]$$
wherein
RR₀ is a removal rate measured after performing polishing using the polishing composition under the following polishing conditions:
a temperature of 15 to 25° C., a polishing head rotation speed of 87 rpm, a platen rotation speed of 93 rpm, an injection rate of the polishing composition of 90 ml/min, a polishing time of 60 second, use of a wafer including an amorphous carbon layer having a thickness of 2,000 Å and a size of 4 cm (width)×4 cm (length), and use of a mini-polisher;
RR_{f} is a removal rate measured after performing polishing using the polishing composition under the polishing conditions after storing the polishing composition at 45° C. for 10 hours and cooling the polishing composition to 15 to 25° C.; and
RR₀ and RR_{f} are removal rates obtained by measuring the thicknesses of the amorphous carbon layer before and after performing polishing under the polishing conditions.

8. A method of preparing a polishing composition for a semiconductor process, the method comprising steps of:
a) preparing a polishing solution by mixing a stabilizer and an accelerator in a solvent;
b) adjusting a pH of the polishing solution to 2 to 5 by adding a pH adjusting agent to the polishing solution; and
c) mixing a surfactant and abrasive particles with the polishing solution having a pH of 2 to 5,
wherein the stabilizer is a compound represented by Formula 1 below: 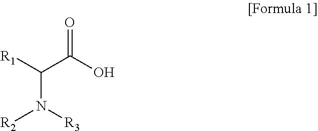
wherein
R₁ to R₃ are same as or different from one another and are each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent substituent group to form a ring.

9. The method of claim 8, wherein step a) comprises:
preparing a mixed solution by mixing the stabilizer with the solvent; and
preparing the polishing solution by mixing the mixed solution with the accelerator.

10. A method of fabricating a semiconductor, the method comprising steps of:
1) providing a polishing pad comprising a polishing layer;
2) supplying a polishing composition for a semiconductor process to the polishing pad; and
3) polishing a polishing target while allowing the polishing target and the polishing pad to rotate relative to each other so that a polishing-target surface of the polishing target comes into contact with a polishing surface of the polishing layer,
wherein the polishing composition contains abrasive particles, an accelerator, and a stabilizer, wherein the stabilizer is a compound represented by Formula 1 below: 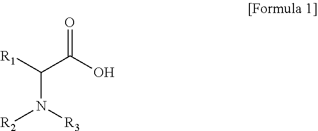
wherein
R₁ to R₃ are the same as or different from one another and are each independently selected from the group consisting of hydrogen, a substituted or unsubstituted alkyl group having 1 to 10 carbon atoms, a substituted or unsubstituted cycloalkyl group having 3 to 10 carbon atoms, a substituted or unsubstituted alkenyl group having 2 to 10 carbon atoms, a substituted or unsubstituted alkynyl group having 2 to 10 carbon atoms, a substituted or unsubstituted aryl group having 6 to 30 carbon atoms, and a substituted or unsubstituted heteroaryl group having 3 to 30 carbon atoms, and
R₁ to R₃ may each independently be combined with an adjacent substituent to form a ring.
